(19) United States
(12) Patent Application Publication
(10) Pub. No.: US 2026/0231531 A1
(43) Pub. Date: Aug. 6, 2026

(54) VERTICALLY INTEGRATED TRANSISTORS AND METHOD

(71) Applicant: KING ABDULLAH UNIVERSITY OF SCIENCE AND TECHNOLOGY, Thuwal (SA)

(72) Inventors: Xiaohang LI, Thuwal (SA); Saravanan YUVARAJA, Thuwal (SA)

(21) Appl. No.: 19/142,539

(22) PCT Filed: May 24, 2024
(86) PCT No.: PCT/IB2024/055093

§ 371 Date: Jun. 23, 2025

Related U.S. Application Data
(60) Provisional application No. 63/469,266, filed on May 26, 2023.

(51) Int. Cl. H10D 88/00; H10D 30/01; H10D 30/67; H10D 86/40; H10P 14/20; H10P 14/24; H10P 14/60; H10P 14/68

(52) U.S. Cl. CPC H10D 88/00; H10D 30/0312; H10D 30/6734; H10D 30/6755; H10D 86/423; H10P 14/24; H10P 14/6334; H10D 30/6758; H10P 14/3426; H10P 14/683

(57) ABSTRACT

A method for making a vertically integrated circuit includes providing an amorphous oxide semiconductor substrate, forming a first thin-film transistor over the amorphous oxide semiconductor substrate by using one or more deposition techniques at temperatures equal to or lower than 110° C.; depositing a buffer layer over the first thin-film transistor, wherein the buffer layer has a melting temperature higher than 110° C.; and forming a second thin-film transistor directly over the buffer layer by using the one or more deposition techniques at temperatures equal to or lower than 110° C., to form the vertically integrated circuit. Each of the first and second thin-film transistors has a metal oxide channel.

### CROSS-REFERENCE TO RELATED APPLICATIONS

This application claims priority to U.S. Provisional Patent Application No. 63/469,266, filed on May 26, 2023, entitled “THREE-DIMENSIONAL INTEGRATED METAL-OXIDE TRANSISTORS,” the disclosure of which is incorporated herein by reference in its entirety.

### BACKGROUND OF THE INVENTION

### Technical Field

Embodiments of the subject matter disclosed herein generally relate to a three dimensional (3D) vertically integrated transistors and method for making the same, and more particularly, to a bonding-free, 3D monolithic vertical integration of thin-film transistors.

### Discussion of the Background

Low thermal budget (LTB) electronics, distinct from traditional semiconductor devices, are manufactured on non-conventional substrates such as paper, plastic, or metal foil. These electronics typically utilize thin-film semiconductors like organics, amorphous oxide semiconductors (AOS), or amorphous silicon. AOS has garnered significant interest due to its advantages like affordability, low-temperature fabrication requirements, high carrier mobilities, transparency in the visible spectrum, mechanical flexibility, and scalable deposition methods, which are more favorable compared to amorphous silicon.

Despite these advantages, advancements in AOS-based thin film transistor (TFT) integrated circuits (ICs) are scarce. A major hurdle is the absence of an appropriate technology scaling in AOS TFT ICs, a stark contrast to the scaling seen in conventional silicon transistors, incorporated by Moore's law. While AOS TFTs have been used in applications ranging from simple logic gates to 32-bit microprocessors, the growth in AOS ICs has been slow. This sluggishness is attributed to the low resolution and large feature size of current fabrication techniques, which limit transistor count in a given area. To expand beyond display applications, AOS TFT-based ICs need technology scaling akin to More-Moore's law.

To overcome these challenges and improve scaling in AOS IC technology, researchers are exploring the concept of monolithic 3D vertical integrated circuits (Mo3D-ICs). The predominant method for realizing Mo3D-ICs involves a bonding process, categorized into wafer-on-wafer, die-on-die, and die-on-wafer. However, this approach faces challenges like low power density, high-temperature bonding processes, and lack of industry standards, hindering its widespread adoption.

Recent research has focused on layer-by-layer (LbL) or additive manufacturing (AM) methods for a more efficient, cost-effective, and scalable approach to Mo3D-IC technology. Several studies have demonstrated the successful implementation of these techniques. For example, [1] developed hybrid complementary transistors using solution-processed ZnO and diF-TESADT channel layers, achieving balanced electron and hole mobilities. The team in [2] demonstrated the effective vertical stacking of ZnO NW FETs for nano-floating gate memory and inverter applications. The team in [3] showcased a complex three-dimensional complementary inverter using a vertically stacked p-channel SnO TFT and an n-channel IGZO TFT.

However, these Mo3D integrated oxide semiconductor-based transistors have limitations, including high-temperature processing requirements, low yields, and incompatibility with scalable CMOS integration. Thus, there is a need for a new, scalable and efficient approach for making AOS Mo3D-IC systems.

### SUMMARY OF THE INVENTION

According to an embodiment, there is a method for making a vertically integrated circuit, and the method includes providing an amorphous oxide semiconductor substrate, forming a first thin-film transistor over the amorphous oxide semiconductor substrate by using one or more deposition techniques at temperatures equal to or lower than 110° C., depositing a buffer layer over the first thin-film transistor, where the buffer layer has a melting temperature higher than 110° C., and forming a second thin-film transistor directly over the buffer layer by using the one or more deposition techniques at temperatures equal to or lower than 110° C., to form the vertically integrated circuit. Each of the first and second thin-film transistors has a metal oxide channel.

According to another embodiment, there is a vertically integrated circuit that includes an amorphous oxide semiconductor substrate, a first thin-film transistor located over the amorphous oxide semiconductor substrate, a buffer layer located over the first thin-film transistor, wherein the buffer layer has a melting temperature higher than 110° C. and smaller than 290° C., and a second thin-film transistor directly located over the buffer layer. A thickness of the buffer layer is between 40 and 60 nm, and each of the first and second thin-film transistors has a metal oxide channel.

### BRIEF DESCRIPTION OF THE DRAWINGS

For a more complete understanding of the present invention, reference is now made to the following descriptions taken in conjunction with the accompanying drawings, in which:

FIGS. 1A to 1C are schematic diagrams of a 3D monolithic integration of In₂O₃ thin film transistors including a bottom gate transistor, a top gate transistor, and a dual gate transistor;

FIG. 2 illustrates a free-bonding, vertically integrated, 10-stack of thin-film transistors structure formed on AOS;

FIG. 3 is a flowchart of a method for making the structure shown in FIG. 2;

FIGS. 4A to 4E illustrate the various stages of forming the structure of FIG. 2 based on the method illustrated in FIG. 3 and FIG. 4F illustrates a table that presents each layer of the structure of FIG. 2 and its composition;

FIG. 5A illustrates a 3D stacked dual-gate device architecture with 100 nm gate thickness having region-A, region-B, region-C, and region-D; FIG. 5B illustrates gate leakage paths in region-A, FIG. 5C illustrates gate leakage paths in region-B, FIG. 5D illustrates gate leakage paths in region-C, and FIG. 5E illustrates gate leakage paths in region-D;

FIG. 5F illustrates the root mean square (RMS) roughness of the active layers in the IC device of FIG. 2;

FIGS. 6A, 7A, and 8A illustrate the transfer characteristics, FIGS. 6B, 7B, and 8B illustrate the mobility, and FIGS. 6C, 7C, and 8C illustrate the subthreshold swing behavior of ICs made with bottom gate transistors, top gate transistors, and dual gate transistors, respectively;

FIG. 9A illustrates an inverter made using two dual gate transistors located at different layers in a ten stack structure vertically integrated, FIG. 9B schematically illustrates the circuitry of the voltage inverter of FIG. 9A, FIG. 9C illustrates the voltage-transfer characteristics (VTCs) of nine different inverters measured at V_{DD}=15 V, and FIG. 9D illustrates the signal gain calculated from the VTCs in FIG. 9C;

FIGS. 10A to 10C show the transfer curves for a configurable inverter circuit having 3D-stacked transistors for different V_{TG1} values of +10 V, 0 V, and −10 V, respectively;

FIG. 11A is a schematic representation of a top-gate tunable unipolar inverter circuit and FIG. 11B shows the VTC characteristics of the optimized circuit operating at V_{TG1}=−10 V and tested for V_{TG2} voltages of +10 and −10 V including the gain characteristics (dotted lines);

FIG. 12 is a benchmark graph comparing the IC of FIG. 2 with the reported state-of-the-art literature based on various factors such as the number of vertical stacks, transistor mobility, and processing temperature.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a Mo3D-IC made of metal-oxide transistors at room temperature (RT). However, the embodiments to be discussed next are not limited to metal-oxide transistors or to processes performed at RT, but may be applied to other type of transistors and other temperatures.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

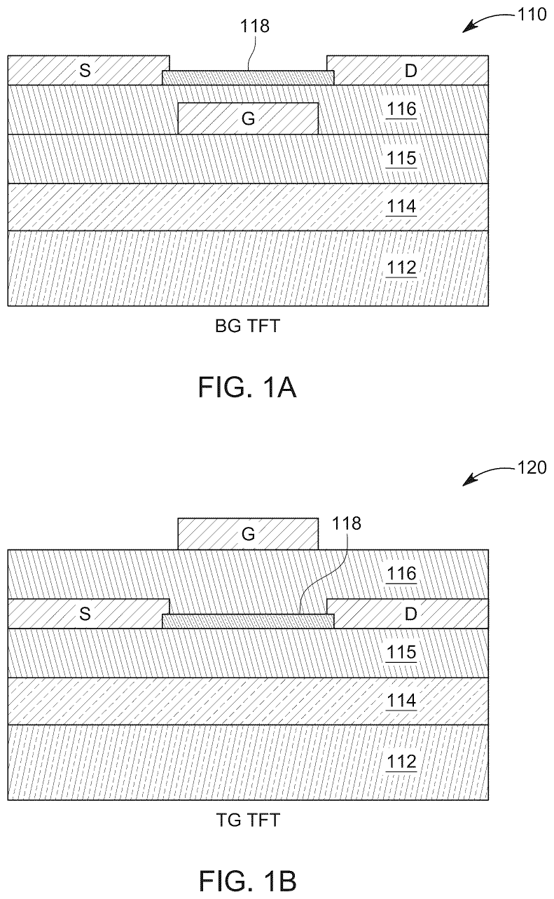

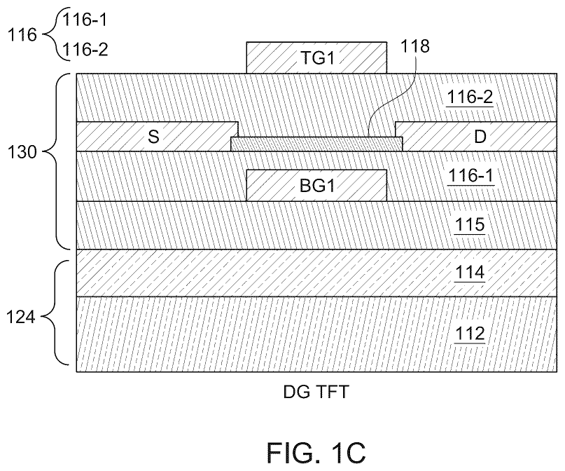

According to an embodiment, an up-scalable manufacturing process of 3D-integrated metal-oxide transistors and circuits processed at room or low temperature is introduced. This process relies on established material and processing technologies and offers the potential for facile, vertically integrated circuits with enhanced functionalities and performance. The Mo3D-IC may include plural bottom-gate (BG) transistors, plural top-gate (TG) transistors, plural dual gate (DG) transistors, or a combination of them. FIG. 1A schematically illustrates a BG transistor 110, FIG. 1B schematically illustrates a TG transistor 120, and FIG. 1C schematically illustrates a DG transistor 130. Each one of these transistors may include a substrate 112, for example, Si, an isolation layer 114 located (e.g., directly) above the substrate 112, for example, made of SiO₂, a buffer 115 located (e.g., directly) above the isolation layer 114, for example, made of parylene-C, a dielectric 116, for example, made of parylene-C, a source S, a drain D, and a gate G, all made of Aluminum, and a channel 118 (e.g., made of a metal oxide, for example, In₂O₃, but possible to be made of different materials). For the BG transistor 110, the gate G is made in the dielectric 116, directly above the buffer 115 and the channel 118 is located on the dielectric 116. For the TG transistor 120, the gate G is located on the dielectric 116, and the channel is made at an interface between the dielectric 116 and the buffer 115. For the DG transistor 130, there is a first gate G1 located directly on the buffer 115, at the interface between the buffer 115 and a first portion 116-1 of the dielectric 116, and a second gate located on a top surface of a second portion 116-2 of the dielectric 116. The dielectric 116 is split into two portions 116-1 and 116-2 by the channel 118, source S, and drain D, as illustrated in FIG. 1C. Each of the transistors 110, 120, and 130 is an n-channel In₂O₃ TFTs in the figures. However, the In₂O₃ in the channel 118 may be replaced by another oxide or another material altogether as long as its processing temperature is RT or less than 110° C. In one embodiment, the drain and source are partially formed over the channel 118. The parylene-C was used as the buffer and dielectric material due to its excellent insulating properties, facile processing, and high conformity.

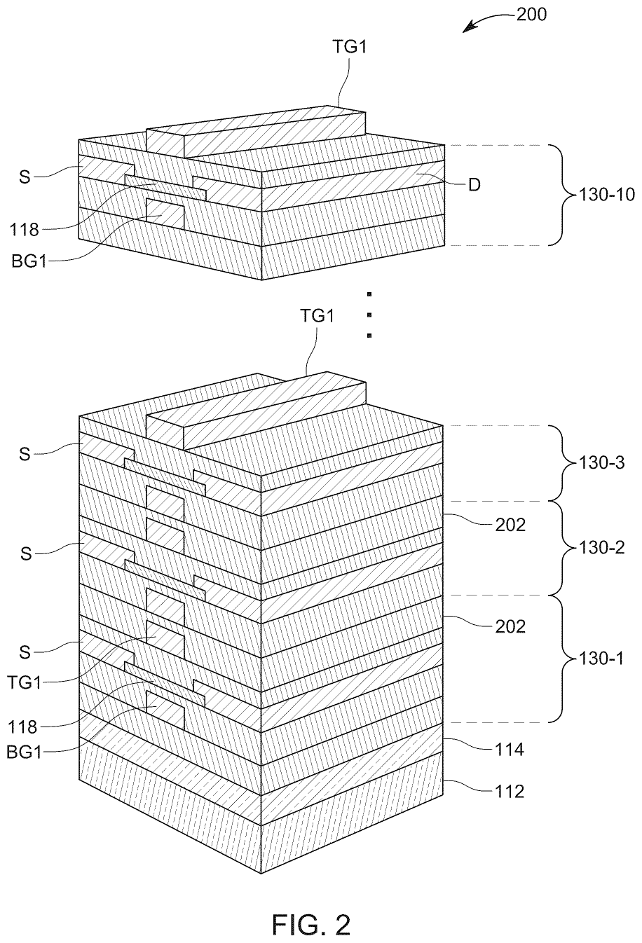

The processing methodology for an IC, to be discussed now, allows multiple layers of functional devices 130 (or other devices, 110, 120) to be sequentially processed on top of each other, at near RT without (or free of) bonding. This processing methodology does not use vertical interconnect access (VIAs) for interconnection. In one embodiment, it is possible to use interconnects in the structure. By reconfiguring the vertical and spatial locations of the bottom and top gate electrodes during the stack processing, it is possible to fabricate dual-gate transistors (see FIG. 1C) that follow an underlap transistor architecture. The term “underlap” refers in this disclosure to the absence of overlap between the gate-source and gate-drain regions. The processing methodology allows multiple layers of functional devices to be sequentially processed on top of each other at near room temperature. FIG. 2 shows a schematic representation of a vertically integrated 10-stack (10-S) DG In₂O₃ transistors, forming a Mo3D-IC 200 (called “IC 200” in this disclosure), which includes DG transistors 130-1 to 130-10 with underlapping.

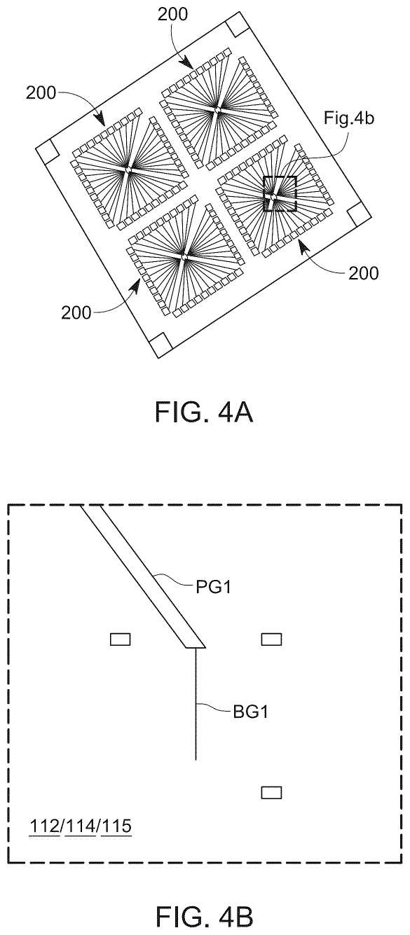

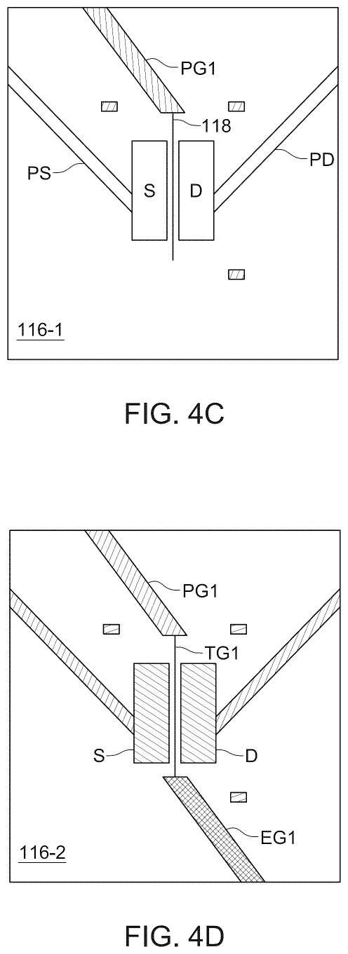

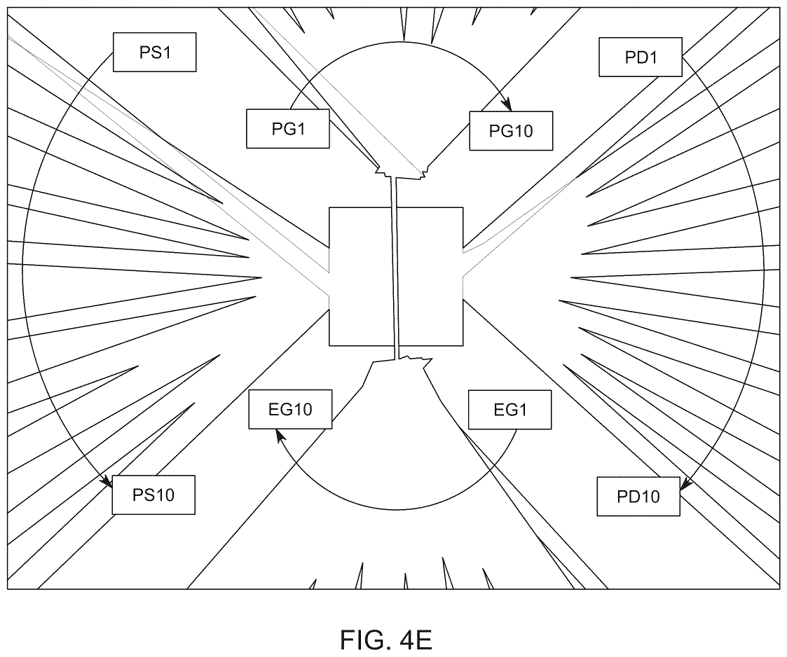

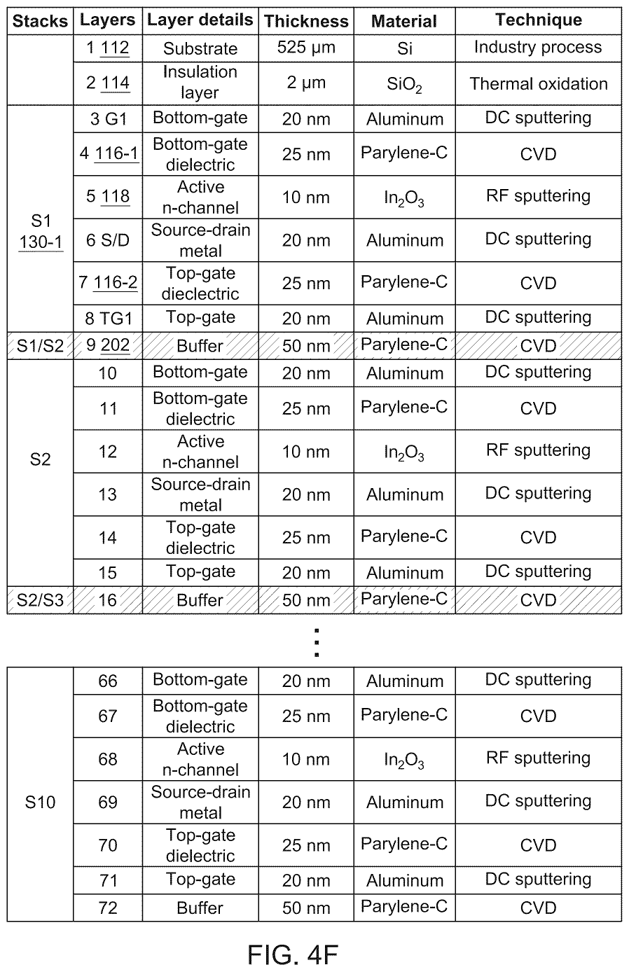

A method for making the IC 200 is now discussed with regard to FIGS. 2 to 4E. The final product is illustrated in FIG. 4A. Note that this figure show four IC 200. However, any number of ICs may be made. The method 300 starts with thermally growing a SiO₂ layer 114 (about thick 2 μm) on the highly doped p-type Si substrate 112, to obtain, for example, the layers of Si/SiO₂, also referred to as the “substrate 124” in this disclosure. Thus, the method provides the substrate 124 in step 302. This Si/SiO₂ substrate 124 (i.e., 112/114) is subjected to a standard cleaning procedure using acetone, isopropyl alcohol (IPA), and deionized water for about 5 min each. A buffer layer 115 may be made to cover the substrate 124. The first stack DG transistor 130-1 fabrication (the final IC 200 is illustrated in FIGS. 2 and 4A) starts in step 304 by DC-sputtering and lithography patterning of a bottom gate BG1 made of aluminum (Al) (about 20 nm thick) on the Si/SiO₂ substrate 124 and the buffer layer 115, as schematically illustrated in FIG. 4B. FIG. 4B also shows a pad PG1 electrically connected to the bottom gate BG1. In one embodiment, the pad PG1 is considered to be part of the bottom gate BG1 and they are collectively referred to as “gate electrode.”

In the following, various deposition techniques are used for forming the various layers of the IC 200. All these techniques are referred to as “deposition techniques.” The deposition techniques may include chemical vapor deposition, physical vapor deposition, atomic layer deposition, molecular beam epitaxy, epitaxy, etc. All the deposition techniques used in the embodiments of this disclosure are performed at RT or at low temperatures, i.e., a temperature lower than 110° C.

On top of the Al gate BG1, a first portion 116-1 of a parylene-C layer 116-1 (about 25 nm thick) is made in step 306 as BG dielectric deposited at room temperature using a specialty coating system (SCS) chemical vapor deposition (CVD) coating system. Note that first portion 116-1 of the dielectric layer 116 fully covers the bottom gate BG1 and pad PG1. In step 308, the In₂O₃ channel layer 118 is formed over the first portion 116-1 of the dielectric layer 116, as also illustrated in FIG. 4C. Note that bottom gate BG1 is covered in this figure by channel layer 118, and thus it is not visible. Around 10 nm In₂O₃ active channel layer 118 is deposited at room temperature using a radio frequency (RF)-sputtering system. The sputtering conditions, for example, 100 W, 20 sccm Ar, and 20 sccm O₂ flow at 10 mTorr pressure, may be optimized to deposit the active channel layer 118.

In step 310, source and drain Al electrodes S and D are patterned above and underlapping the active channel layer 118, as illustrated in FIG. 4C. Associated pads PS and PD are also formed in electrical contact with the corresponding source and drain electrodes. The pads PS, PD, and PG are used later for electrically connecting the various layers/structures of the IC 200 to each other or to external electronics. In step 312, a second portion 116-2 of the parylene-C dielectric 116 is deposited, at room temperature using the same SCS CVD system, over the source S and drain D, as schematically illustrated in FIG. 4D.

Note that the inventors have initially investigated the feasibility of creating dual-gate transistors using high-k dielectrics such as HfO₂ and Al₂O₃. However, after depositing the top-gate HfO₂ dielectric on the surface of the bottom-gate device, the channel current increased significantly, and the device lost gate field control. This issue is attributed to the permanent damage of the ultra-thin In₂O₃ channel by the high-temperature (250° C.) atomic layer deposition (ALD) process of HfO₂.

The inventors also explored the use of Al₂O₃ as both bottom-and top-gate dielectrics 116-1 and 116-2, respectively. Similar to the HfO₂ case, this device lost gate control after the deposition of the Al₂O₃ top-gate dielectric. While the literature has addressed similar issues through annealing and plasma processes, it is noted that these high-temperature processes can damage other devices in a vertically stacked configuration, leading to increased process complexity and potential failure in 3D integration. These high-temperature annealing and plasma-intensive techniques are major obstacles preventing researchers from implementing more than two vertically stacked transistors.

To circumvent these issues, the inventors discovered that replacing the conventional high-temperature processed high-k dielectric with a room-temperature processed parylene-C dielectric material 116 solved the above mentioned problems. Parylene-C material is available in powder form. This powder can be deposited as a thin film using chemical vapor deposition (CVD) by a specialty coating system (SCS) manufacturer. The thickness of the parylene-C film can be controlled by the weight of the powder (measured in grams). An interesting feature of this material is that it is possible to deposit parylene-C films as thin as 10 nm and up to a maximum of several micrometers.

The inventors have tested the leakage characteristics for different parylene-C thicknesses. For this analysis, the inventors have used a cross-bar device structure and the cross-bar structure has been selected to be 5 μm×5 μm. The thickness of both the top and bottom electrodes is 20 nm for this test. The inventors found that when the thickness of parylene is 10 nm, the device exhibits high leakage (10⁻³ A) at V_{GS}=2 V. This thickness falls into what it is considered a red zone, referring to the “leakage” area. However, when the thickness is increased to about 25 nm (or between 20 and 30 nm), the device shows no leakage (~10⁻¹² A) within a ±12 V range. This thickness is suitable for gate dielectrics in the 10-stack IC 200. Furthermore, the device shows no significant leakage (~10⁻¹¹ A) within a ±23 V range when the parylene-C thickness is 50 nm. Parylene-C at this thickness may be a good choice for a buffer to electrically isolate two vertically stacked transistors. The observed multifunctional properties of room-temperature-deposited parylene-C have helped the inventors realize the challenging 3D 10-stack oxide transistors.

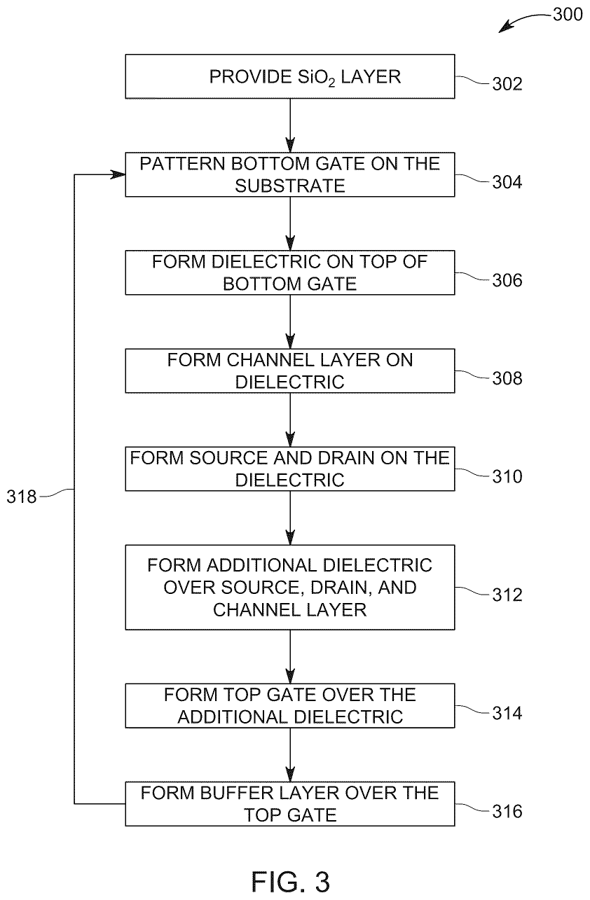

Returning to the method of FIG. 3, in step 314, the first stack (DG transistor) 130-1 was completed by DC sputtering the Al top gate TG1. FIG. 4D shows the top gate TG1 covering channel layer 118. The figure also shows an associated electrode EG1 electrically connected to the top gate TG1. Because FIG. 4D is a top view figure, it appears that PG1 is electrically connected to the TG1, but that is not the case. PG1 is electrically and mechanically connected only to BG1. EG1 is electrically and mechanically connected only to TG1. Channel layer 118 is not electrically connected to either BG1 or TG1.

In step 316, about 25 nm of parylene-C is used to make a layer 202 over the top gate TG1, as schematically illustrated in FIG. 2. The thickness of the parylene-C layer 202 may be between 40 and 60 nm. The table in FIG. 4F shows the order of the layers discussed above and their characteristics and deposition methods. Layer 202 is used as buffer layer between the first structure (dual gate transistor) 130-1 formed above, and the next structure (dual gate transistor) 130-2 in this embodiment. Note that other structures may be used instead of the DG transistor 130, for example, top gate transistor, bottom gate transistor, etc. for making the IC 200. In other words, the IC 200 may include a stack of only top gate transistors or a stack of only bottom gate transistors, or a stack of other semiconductor elements, or a stack of mixed elements, for example, one or more of the top gate transistor, bottom gate transistor, and dual gate transistor.

The inventors performed a gate leakage analysis for a 100 nm gate electrode thickness. After using parylene-C as the dielectric, the inventors fabricated the 10-stack oxide transistors. Over the 100 nm thick gate, a 25 nm parylene-C layer was deposited using the SCS CVD system at room temperature. Following the dielectric deposition, the In₂O₃ channel 118 was deposited and the source/drain contacts to complete the bottom-gate transistor. Surprisingly, the inventors observed leakage at a V_{GS} range of ±3 V in this device transistor configuration. Ideally, with a dielectric thickness of around 25 nm, the device should not exhibit leakage at such a low voltage range. To address this issue, the inventors experimented with increasing the dielectric thickness for the same thick gate 100 nm electrode and found that gate leakage was prominent when the dielectric thickness was less than or equal to 60 nm for the device having a gate electrode thickness of 100 nm. This finding contradicted the known data.

Then, the inventors reduced the gate electrode thickness from 100 nm to about 20 nm. Contrary to what is known in the field, for the transistor with a gate electrode thickness of about 20 nm, the inventors observed no gate leakage when the parylene-C thickness was about 25 nm. This unexpected outcome is particularly interesting because there are no existing reports that explain the impact of gate electrode thickness engineering on gate leakage performance in such devices.

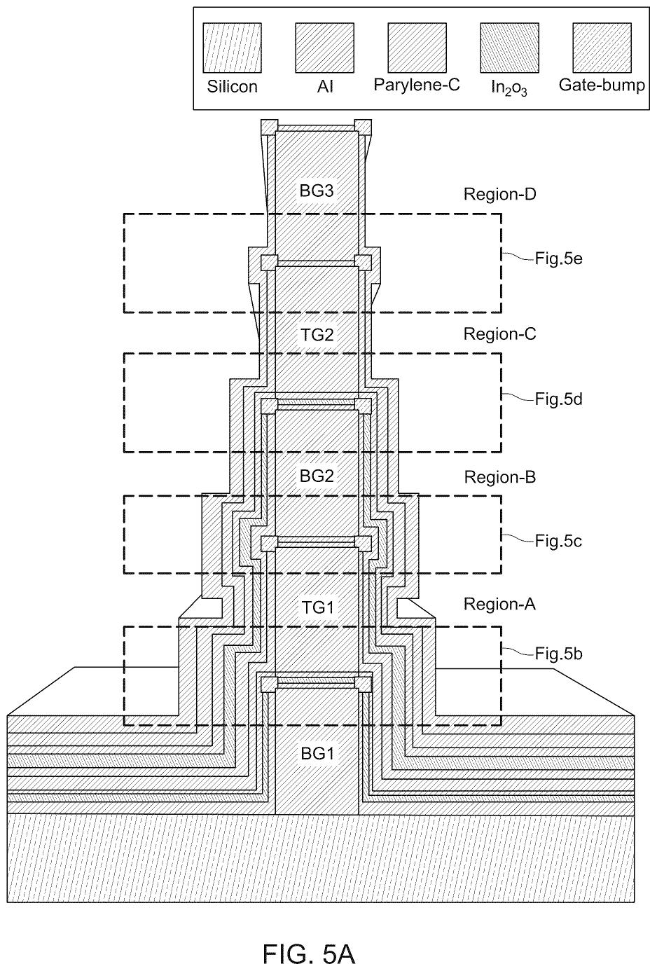

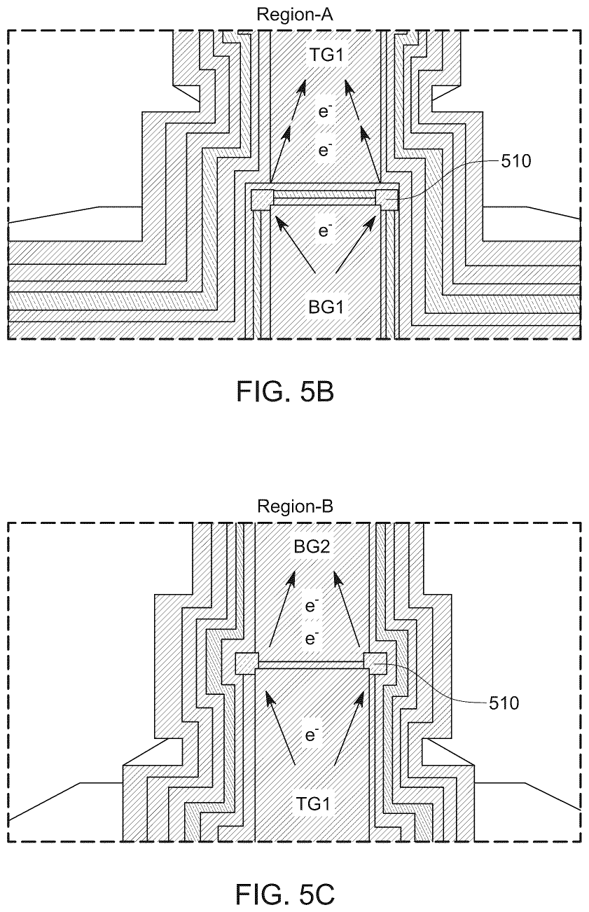

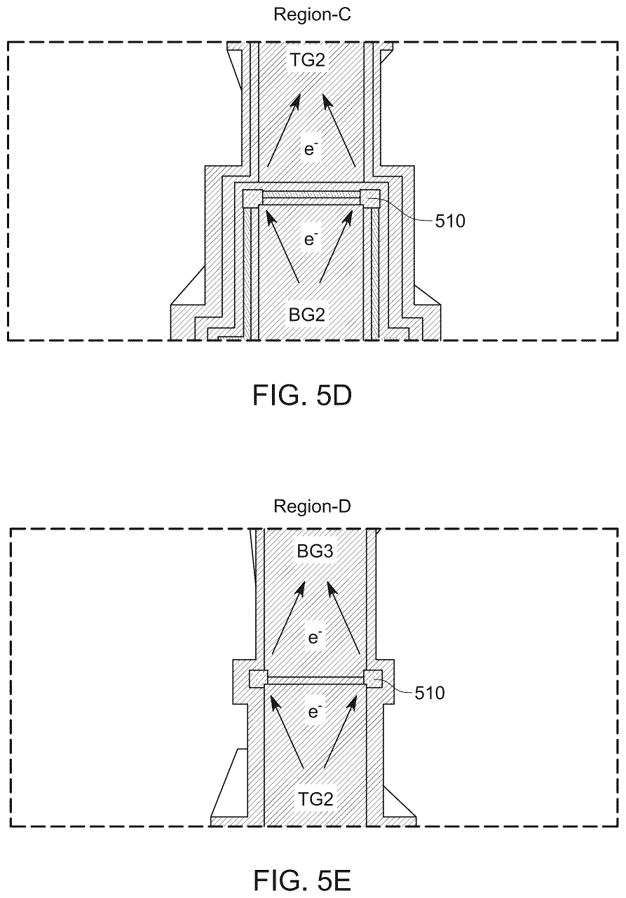

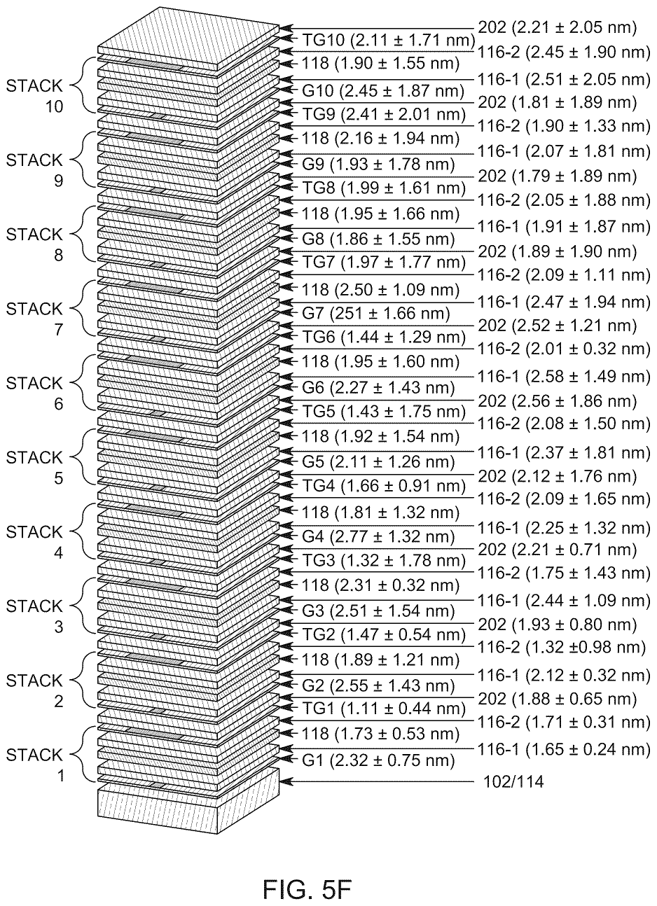

The inventors believe this significant change in gate leakage is associated with different gate electrode thicknesses having a given gate-bump roughness. To investigate the impact of gate thickness on gate leakage in 3D-stacked dual-gate devices, the inventors fabricated two stacks, each comprising dual-gate devices (BG1, TG1, BG2, and TG2), along with only the bottom gate (BG3) of the third stack, as shown in FIG. 5A. The inventors divided the as-fabricated 3D stacks into four regions: region-A, region-B, region-C, and region-D (see FIG. 5A). It is noted that for this analysis, the inventors did not fabricate source and drain contacts.

Region-A, more clearly illustrated in FIG. 5B, focuses on the area between BG1 and TG1 within the first stack's dual-gate architecture. The high bump 510 at the top corners of the patterned BG1 gate likely causes a gate leakage path between BG1 and TG1. Similarly, in region-B, as highlighted in FIG. 5C, the same high bump on the 100 nm thick gate likely leads to metal shorting between TG1 (stack-1) and BG2 (stack-2). This gate leakage phenomenon is also expected in region-C (FIG. 5D) and region-D (FIG. 5E). Therefore, with a gate thickness of 100 nm, gate leakage is dominant both within and between the stacks, leading to failures in the electrical characteristics and reliability of the 3D stacked devices. To reduce the gate leakage, the inventors also fabricated 3D stacked dual-gate devices with an about 20 nm gate thickness (not show). The smaller bump (not shown) at the top corners of the patterned gate suggests minimal gate leakage in regions A, B, C, and D.

The electrical characteristics of 3D stacked devices with different gate electrode thicknesses, 100 nm, 60 nm, and 20 nm, were tested. The gate leakage values were extracted at 10 V (+10 V to −10 V bias sweeping range) and plotted (not shown). The considered bias range exactly matches the range that was used to extract the electrical characteristics of the transistors. The gate leakage data, for 50 devices, in each region with a 100 nm gate thickness indicates that in both region-A and region-C, only 4% of the devices were not leaking. To evaluate the percentage of devices affected due to current leakage, the inventors have considered 2×10⁻⁸ A current as the safe leakage limit level. The percentage of devices exhibiting current leakage below this limit is considered to be safe with no considerable leakage. Meanwhile, all devices exhibited high leakage, indicating shorting in regions B and D.

When the gate electrode thickness was reduced from 100 nm to 60 nm, the slight reduction in the bump led to a marginal increase in the total number of devices showing less leakage below the safe limit for regions A and C. However, the gate leakage in regions B and D for the 60 nm gate thickness, though less than its 100 nm counterpart, still exceeded the safe limit. Thus, it was found that the 3D stacked devices with 100 nm and 60 nm gate electrode thicknesses have poor electrical stability and fail in terms of 3D architecture reliability. However, with a gate thickness of around 20 nm (e.g., between 10 and 30 nm), more than 75% of the devices exhibited extremely low leakage in all regions, showcasing higher reliability compared to their 100 nm and 60 nm counterparts.

Returning to the method of FIG. 3, the stack fabrication process (i.e., steps 304 to 314) was repeated in step 318 nine more times to complete the 10-stack (S1-S10) 200 3D monolithic integration. As previously discussed, step 318 can be repeated any number of times, for example, at least 2. FIG. 4E is a top view of the IC 200, illustrating how the pads PS1 to PS10 (connected to the sources S1 to S10, respectively), the pads PD1 to PD10 (connected to the drains D1 to D10, respectively), the pads PG1 to PG10 (connected to the bottom gates BG1 to BG10, respectively), and the pads EG1 to EG10 (connected to the top gates TG1 to TG10, respectively) are arranged in the IC 200. It is noted that all the pads PS, PD, PG, and EG radially extend away from their corresponding sources, drains, top gates, and bottom gate, so that, in a radial system of reference, a same group of pads occupy a 90 degrees sector. The 10 stack IC 200 of FIGS. 2 and 4A has 72 functional layers: a base Si substrate 112, a SiO₂ insulation layer 114, 30 metal electrode layers (10 BG1+10 TG2+10 source/drain S/D pairs), 10 In₂O₃ channels 118, 30 Parylene-C layers (20 gate-dielectric 116+10 buffers 202). The Table in FIG. 4F summarizes the fabrication method of FIG. 3 for all 72 layers used in the IC 200.

Note that the method of FIG. 3 includes only processing steps that do not require a temperature higher than 150 to 200° C., even 110° C., i.e., a low temperature. For this reason, it is possible to use the parylene-C (melting temperature of about 290° C., up to 350° C.). One skilled in the art would understand that other dielectric materials may be used instead of parylene-C as long as their thermal stability is above 110 and optionally, less than 300° C.

While fabricating the 10-stack 3 D architecture of FIGS. 2 and 4A, the inventors investigated the roughness of each active layer, namely the bottom gate electrode (Al) BG, parylene-C bottom gate dielectric 116-1, In₂O₃ channel 118, parylene top gate dielectric 116-2, the top gate electrode (AI) TG, and parylene-C buffer layers 202 between the stacks. Besides the electrical decoupling effect, achieving a decently smooth surface on the active layers is desired for realizing highly reliable 3D stacked transistors. AFM (Atomic Force Microscopy) images of the active layers were obtained from all 10 stacked devices. The root mean square (RMS) roughness values of all the 10-stack layers can be found in FIG. 5F. From this figure, it is noticeable that all the layers have an RMS roughness of not more than 4 nm (between 1.5 and 4 nm). It is also noted that the roughness is not steadily increasing with each additional stack.

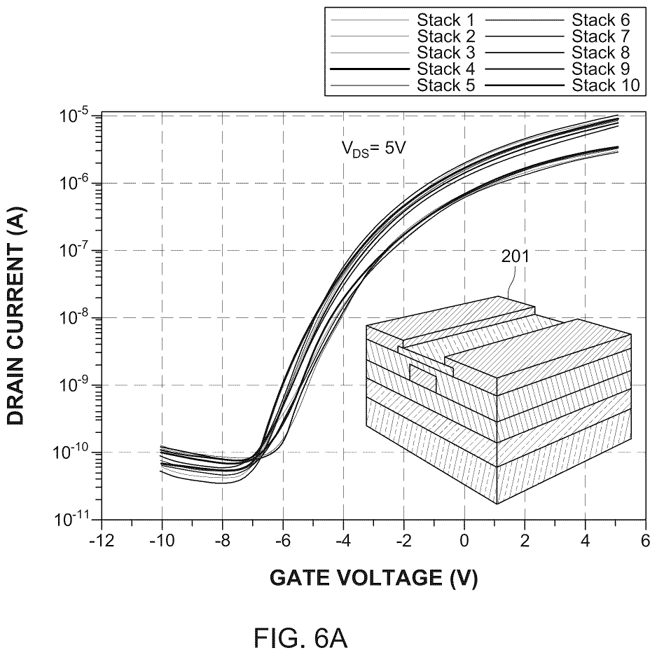

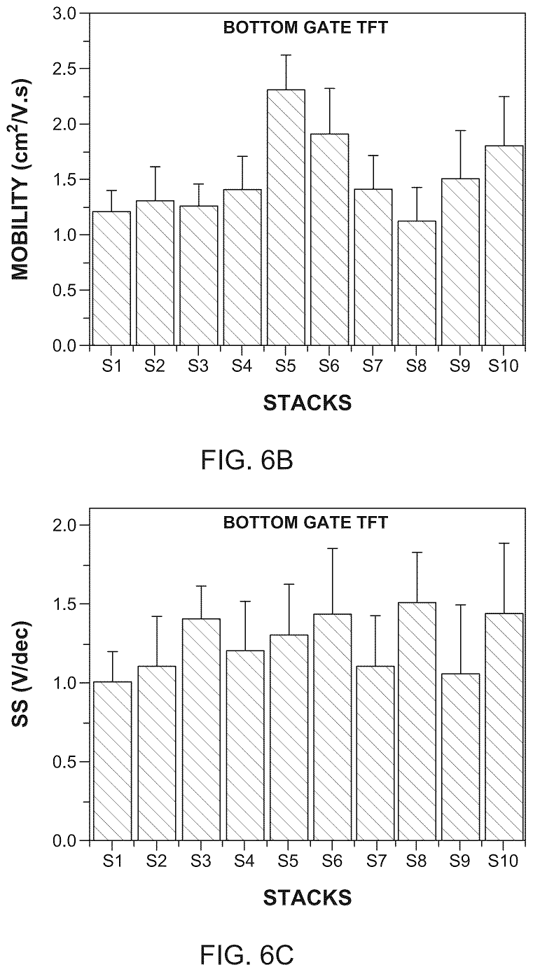

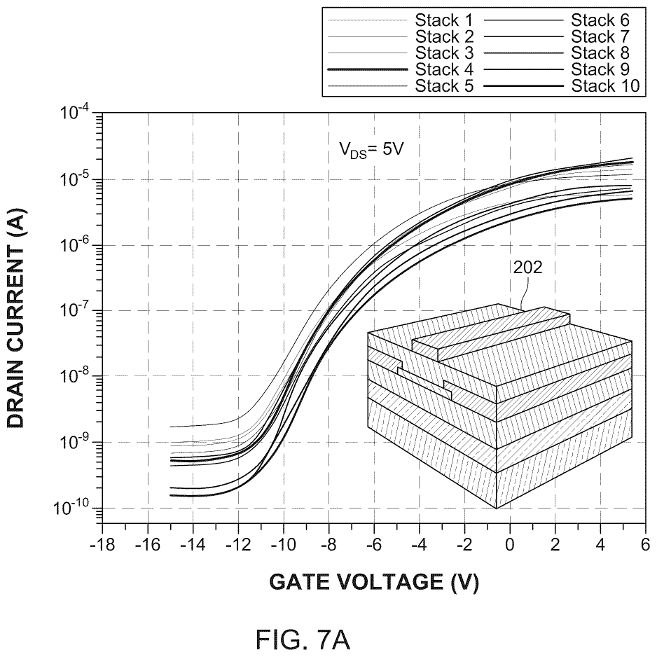

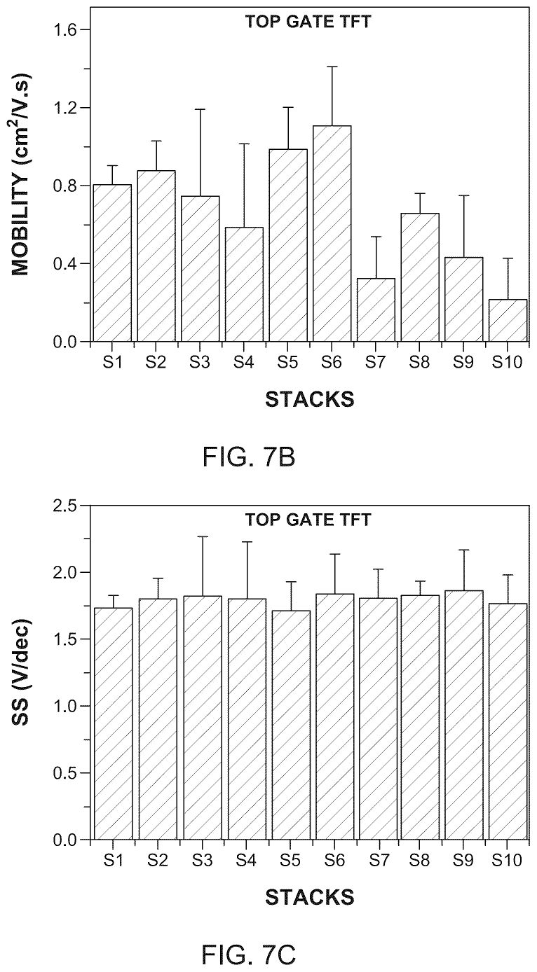

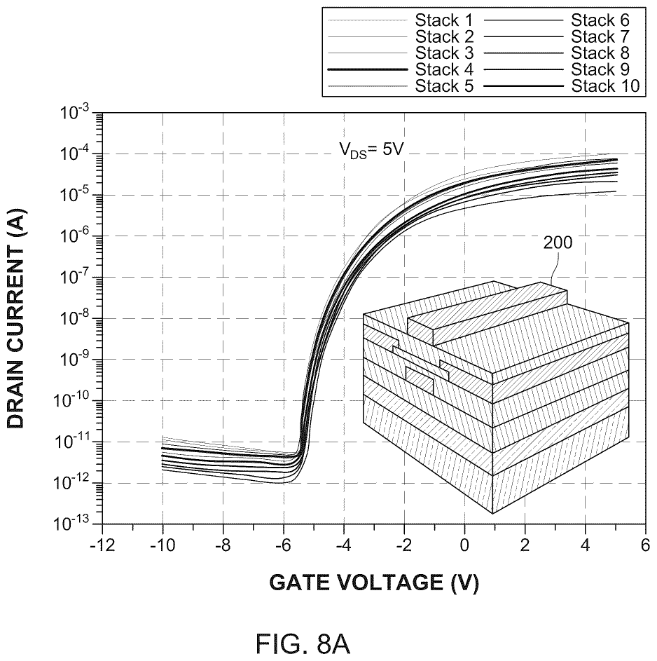

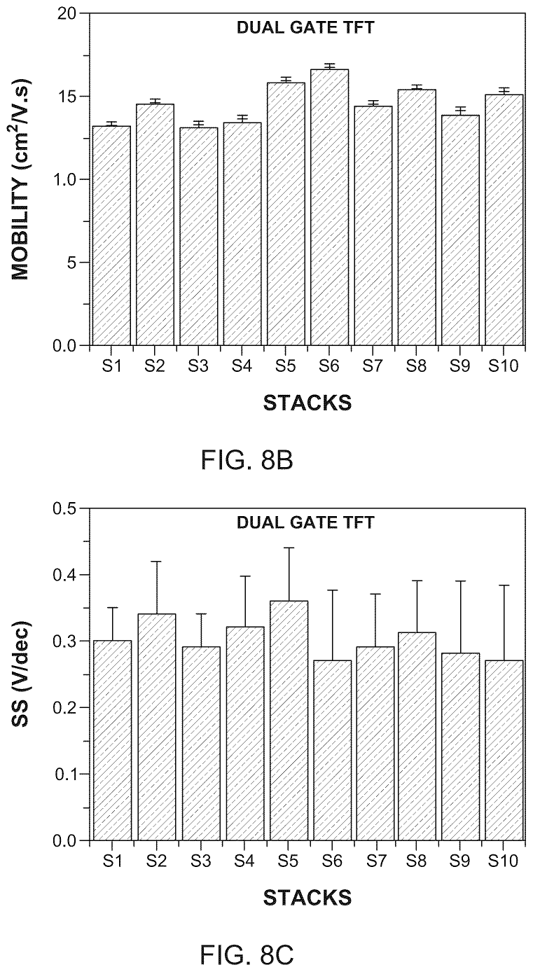

ICs 200 fabricated with only top gate transistors, only bottom gate transistors, and only dual gate transistors were tested by the inventors for determining their characteristics and properties. In this regard, FIGS. 6A to 6C show various characteristics (transfer, mobility, and subthreshold swing (SS) behavior) of an IC made only with bottom gate transistors, FIGS. 7A to 7C show the same characteristics for an IC made only with top gate transistors, and FIGS. 8A to 8C show the same characteristics for the IC 200 shown in FIG. 2, i.e., made with dual gate transistors.

More specifically, FIG. 6A shows the transfer curves for BG devices in different layers across the corresponding IC structure having 10 stacks. The transfer curves were obtained by sweeping V_{GS} from −10 V to +5 V at V_{DS}=+5 V. The threshold voltage (V_{TH}) was calculated to be between −0.52 and −1.54 V, confirming the depletion-mode operation. The output curves (not shown) display linear and saturation regimes, respectively. The gate leakage for all devices is extremely low at about 10⁻¹¹ A, suggesting the formation of a good quality dielectric layer across the 10-S IC structure. Based on these data, the inventors concluded that all the BG devices exhibit identical depletion-mode characteristics, with good reproducibility across the vertically integrated 10-S IC. Additional transistor parameters, including electron field-effect mobility (μ_{FE}), subthreshold swing (SS), current ratio (I_{ON}/I_{OFF}), and transconductance (G_{M}), were also calculated from the transfer and output characteristics. The error bars of the transistor parameters were calculated from devices fabricated in three different chips (110, 120, and 130), each containing four 10-S (as illustrated in FIG. 4A). The I_{ON}/I_{OFF} ratio of the In₂O₃ TFTs in the 10-S was calculated to be about 10⁶. The transistors show modest uFE fluctuation ranging from 1.05 to 2.65 cm²/V·s, as illustrated in FIG. 6B. The accumulation capacitance (C_{ACC}) measurements used to calculate the μ_{FE} were obtained from the mos-capacitor (MOSCAP) characteristics. The ensuing BG TFTs exhibit a high SS value of 1-2 V/dec, as shown in FIG. 6C. From the transfer curves illustrated in FIG. 6A, the G_{M} was also calculated, yielding a value of about 8.51 μS, respectively.

FIG. 7A displays the transfer curves of TG In₂O₃ TFTs in the 10-S IC measured at V_{DS}=5 V. Unlike transistors based on the BG architecture, the TG devices exhibit more negative V_{TH} with values ranging between −5 and −6 V. The gate-leakage current (I_{G}) for all TG devices is extremely low (about 10⁻¹² A) and highlights the good quality of the parylene-C layer that acts as both the buffer and dielectric. The I_{ON}/I_{OFF} ratio of TG devices is one order of magnitude smaller than BG transistors, an effect attributed to the increased OFF current. The electron μ_{FE} range is between 0.5 to 1.13 cm²/V·s, as illustrated in FIG. 7B. Both BG and TG architectures exhibit modest uFE with relatively small variations between different batches. This is attributed to the non-uniformities in the semiconductor/channel interface during sequential growth. These structural variations are evident in the cross-sectional TEM and EDX analysis of the 10-S IC (not shown). The C_{ACC} used to calculate the uFE for the TG devices was obtained from the MOSCAP characteristics. The MOSCAPs show clear accumulation and depletion regions from which the C_{ACC} was extracted. FIG. 7C displays the SS values for the TG TFTs, which are slightly higher than the BG devices (shown in FIG. 6C), indicating a lower-quality parylene-C/In₂O₃ channel interface, which ultimately results to lower FE. Notably, both device architectures exhibit low IG highlighting the excellent insulating nature of the parylene-C interlayers across the vertically integrated 10-S IC.

To improve the operating characteristics of the vertically integrated In₂O₃ TFTs, the inventors developed dual-gate devices using parylene-C as the bottom and top dielectric layer, i.e., using the structure shown in FIG. 1C. FIG. 8A shows the transfer characteristics of the 10 vertically integrated DG transistors measured at V_{DS}=5. The V_{TH} values were calculated from transfer curves (not shown), yielding values between 0.31 to −2.12 V. The saturation currents observed in the output curves (not shown) are consistent with those in transfer characteristics. The I_{G} for the DG devices remains extremely low and in the order of ~10⁻¹² A. Due to the increased G_{M} and reduced I_{OFF}, the ION/OFF ratio for the DG devices is remarkably higher and reaches values up to ~10⁸. Compared to single gate transistors, the DG In₂O₃ TFTs exhibit higher μ_{FE} of ~15 cm²/V·s, as illustrated in FIG. 8B. The inventors assume that this happens due to the high G_{M}, lower C_{ACC}, and excellent gate-field coupling to the channel, in agreement with the literature [3]. The G_{M} and C_{ACC} values for DG devices were calculated from the MOSCAP characteristics. Due to improved gate control and the higher G_{M}, the SS of the DG devices is significantly lower, about 0.4 V/dec as shown in FIG. 8C, compared to single-gate TFTs shown in FIGS. 6C and 7C. Moreover, the small variation in the transistor parameters shown in FIGS. 8B and 8C highlights the enhanced device reliability and robustness for developing 3D-dimensional integrated circuits.

To validate the reproducibility of the proposed 10-stack (10-S) system 200, the inventors performed a) reliability, b) transient, and c) long-term stability studies on 100 bottom-gate, 100 top-gate, and 100 dual-gate devices. The experimental results (not shown) indicate that, when comparing to the BG and TG devices, the DG devices demonstrated better reliability and stability characteristics.

Consequently, the inventors have focused on 10-S DG devices for testing their bias stress stability, including negative bias stress (NBS) and negative bias temperature stress (NBTS). It was found that the thermal stability of 10-stack dual gate transistors is superior. All the transistors belonging to the 10-stack exhibited decent thermal stability till 50° C. However, when the table temperature increased above 75° C., all the stacked transistors under test showcased significant negative shifts in threshold voltage confirming their poor thermal stability performance. The observed poor thermal stability is attributed to the low thermal processing conditions of the layers used in manufacturing the 10-stack transistor IC. Improvements in thermal stability can be achieved by optimizing the growth conditions of active layers and the thermal annealing process. From the electrical characteristics of the 10-stacked BG, TG, and DG devices, significant device-to-device variations are observed. These fluctuations may be attributed to mechanical, electrical, and thermal parameters. In addition to reliability and stability measurements, to explore the potential for scaling down the transistors, the inventors also fabricated and characterized BG, TG, and DG transistors with W (width)=1 μm, L_{g} (gate length)=100 nm, L_{ch} (channel length)=500 nm.

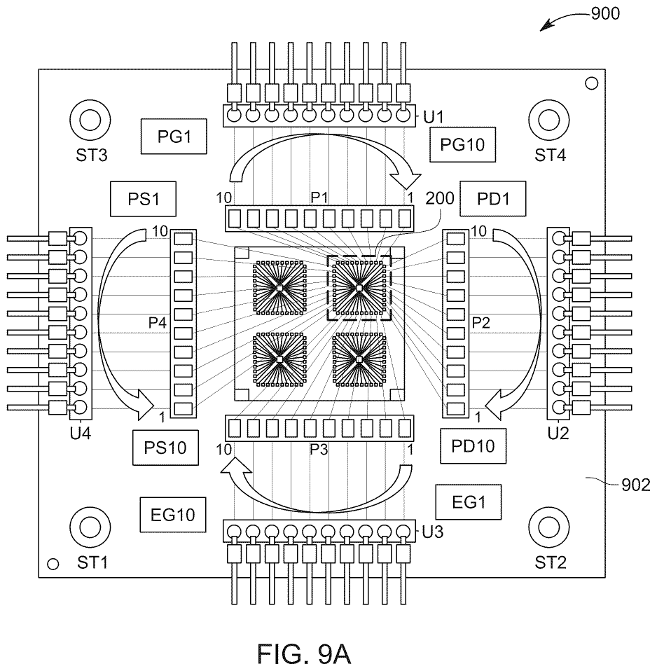

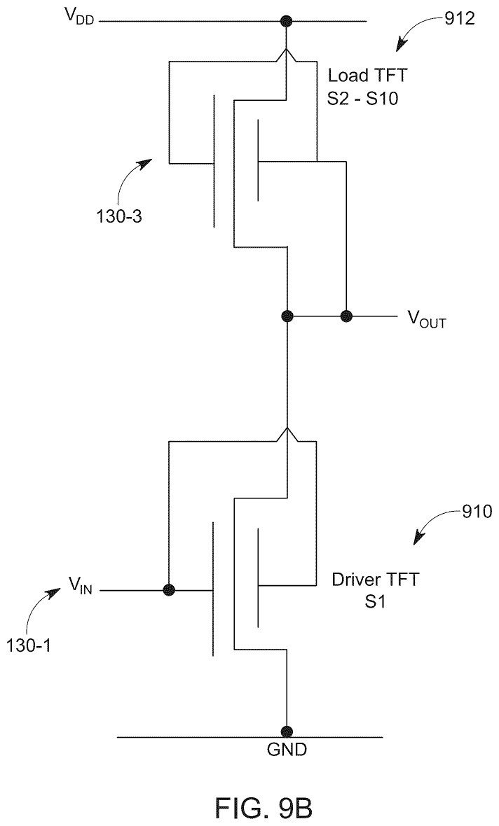

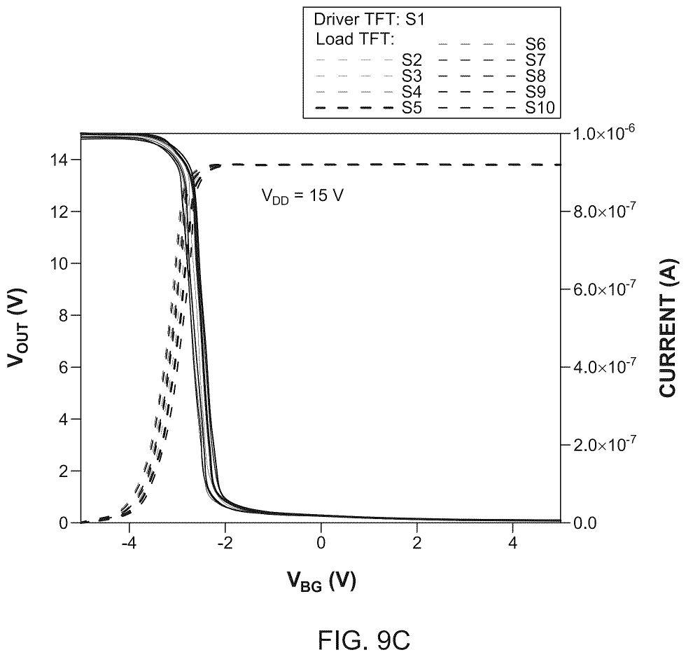

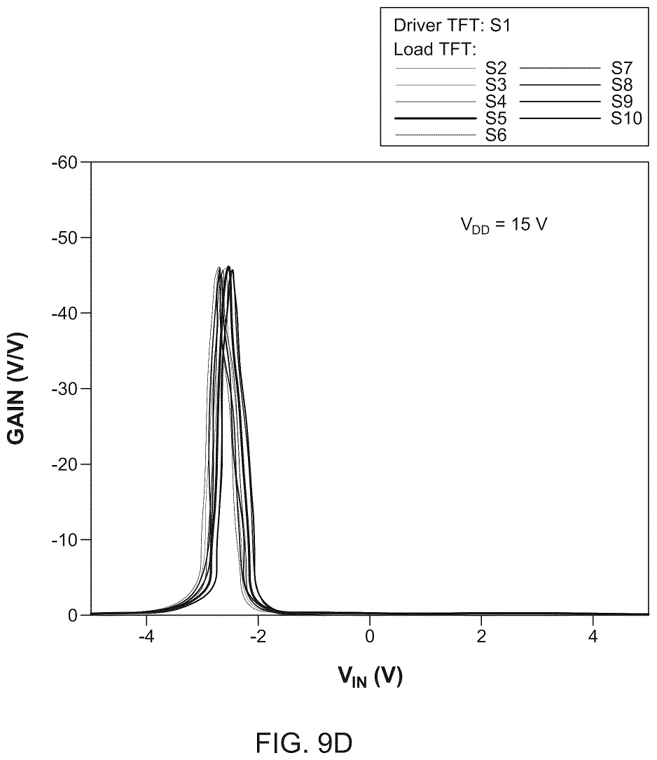

Using the free bonding technology discussed above, the inventors fabricated an NMOS inverter circuit 900 to demonstrate the potential of the 10-S vertically integrated In₂O₃ TFTs IC 200 of FIGS. 2 and 4A. Note that a typical NMOS inverter circuit comprises two n-type transistors, one acting as a driver and the other as a load. Unlike conventional laterally (2D) integrated inverters, the inventors used in this embodiment two vertically stacked transistors 130-1 and 130-3 from the 10-S system 200 for inverter testing. In this embodiment, the separation between two adjacent stacks is just a 50 nm parylene-C buffer layer 202. FIG. 9A displays the completed 10-S chip 900 mounted on a printed circuit board (PCB) 902. Due to their superior operating characteristics, DG devices 130 were chosen to build the inverter circuit 900 shown in FIG. 9B (the figure shows only two devices 130-1 and 130-3 out of the 10 devices 130). Ninety combinations of depletion-load inverter configurations were tested. The biasing conditions used for testing the inverter were V_{IN}=−5 to 5 V and V_{DD}=+15 V. FIG. 9C shows the inverter voltage-transfer characteristics (VTC) of the first nine combinations out of the 90 tested. The stack S1 DG device 130-1 is the driver 910, and the rest of the devices (S2-S10) 130-2 to 130-10 are the depletion-load 912. The inverter trip voltage (V_{Trip}), i.e., the voltage at which the output of the gate transitions from HIGH to LOW, is approx. −2.2 V, consistent with the V_{TH} of the driver device. FIG. 9D shows the gain of the inverter circuits tested, reaching a maximum value of 50 V/V, which is on par with previously reported 3D-stacked circuits. The channel width (W), channel length (L), and gate length (L_{g}) for both driver and load are 500, 15, and 5 μm, respectively.

The gain values obtained from the 90 inverter circuits were also calculated (not shown). Although not optimal, the VTCs of the inverters are very similar, showcasing the reliability of the 3D-integration process adopted in the method of FIG. 3. Further tuning of the device geometry and inverter circuitry is expected to enable further performance optimization.

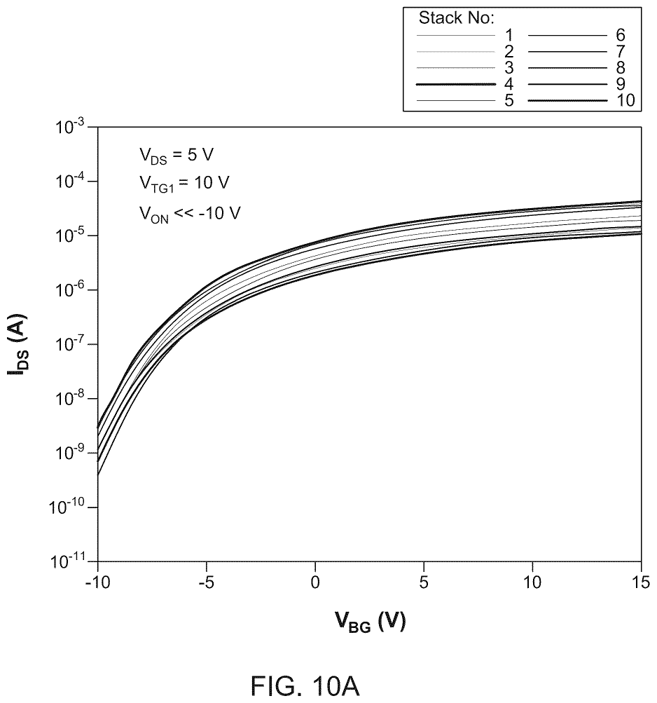

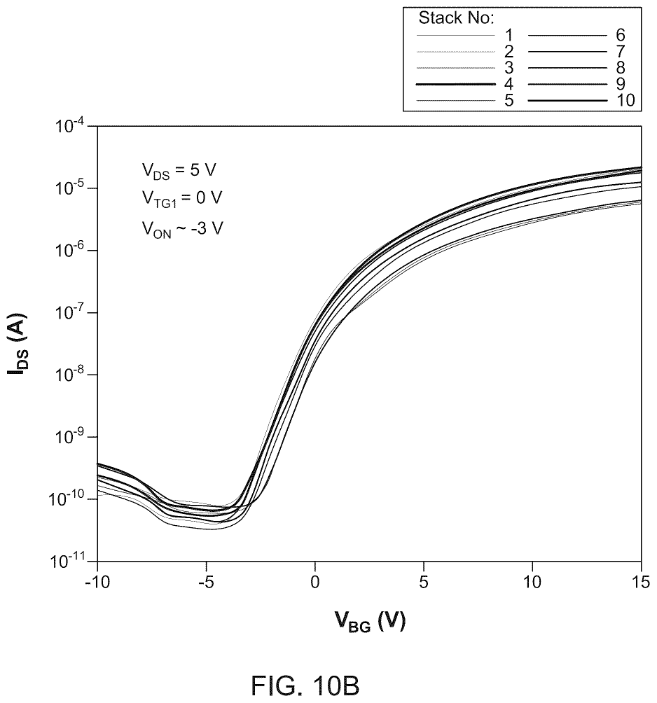

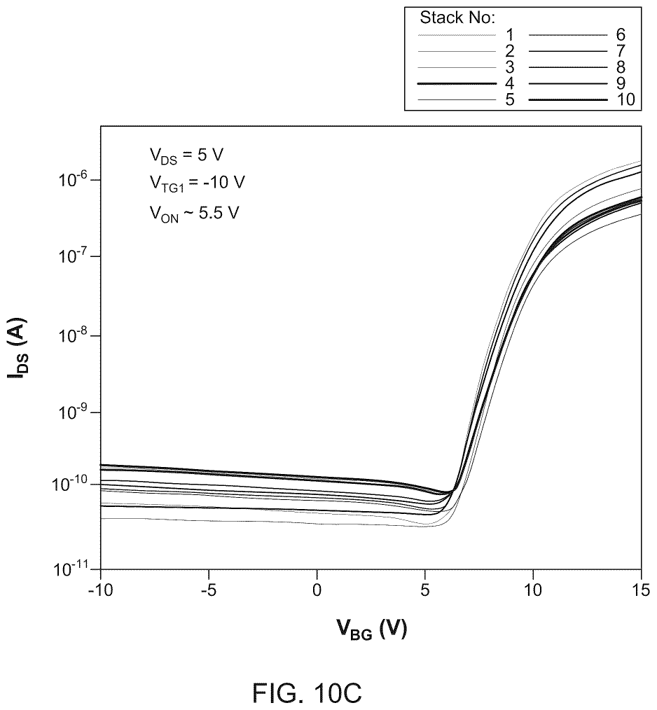

An advantage of the dual-gate transistor architecture illustrated in FIG. 2 is that it facilitates additional connection configurations that lead to increased speed, lower power dissipation, and improved noise immunity compared to conventional single-gate transistors. For example, the two gate terminals BG1 and TG1 for each stack can be shorted (gate-shorted configuration), left floating (gates-floating configuration), or biased at different potentials. By doing so, different switching characteristics by the same device can be achieved. To explore this advantage, the inventors studied the effect of fixed TG bias on the operating characteristics of a DG vertically integrated transistor. The inventors achieve this by sweeping the bottom-gate potential (V_{BG}) while maintaining the top-gate potential (V_{TG1}) at a fixed bias. The V_{TG1} is subjected to different biasing conditions, namely 10, 5, 0, −5, or −10 V. The measured transfer curves for representative dual-gate In₂O₃ TFTs located within the 10-S system are shown in FIGS. 10A to 10C. All transfer curves were obtained at a V_{DS}=5 V and sweeping the V_{BG} between −10 to 15 V. For V_{TG1}=10 V (see FIG. 10A), the positive bias enables additional electron accumulation due to its synergistic effect, which shifts V_{ON} towards more negative voltages (<<−10 V) . In this case, the voltage range applied to the V_{BG} is insufficient to fully deplete the accumulated electrons in the channel. A stepwise reduction of V_{TG1} from 10 V to eventually −10 V leads to a gradual shift of V_{ON} towards more positive voltages, where it reaches values of −7.5 V, −3 V (see FIGS. 10B), 1.5 V, and 5.5 V (see FIG. 10C) for V_{TG1} equal to 5, 0, −5, and −10 V, respectively. This behavior is indicative of fewer accumulated electrons in the channel, the concentration of which can then effectively be tuned via the V_{BG}. These results highlight the ability of the dual-gate architecture to fine-tune the operating characteristics of TFTs located at different levels in the vertically integrated 10-S IC. The layout of each gate electrode in the 10-S IC can be designed to act as a dedicated gate for a single TFT or as a shared/common gate for two transistors located in neighboring stacks (i.e., S1-S2). This unique feature makes the vertically integrated 10-S IC system 200 highly reconfigurable, potentially delivering ultra-high-density integrated circuits. V_{BG} and V_{TG1} in the figures correspond to bottom-gate and top-gate terminals of the driver device. V_{TG2} refers to the top-gate terminal of the load device.

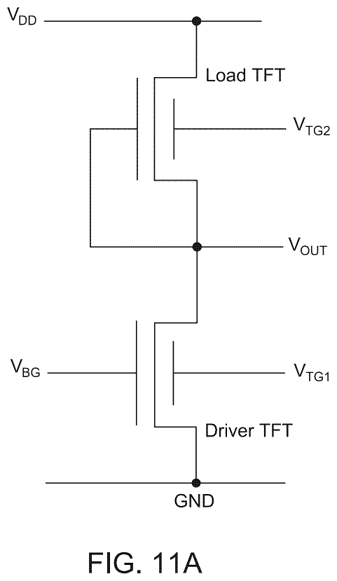

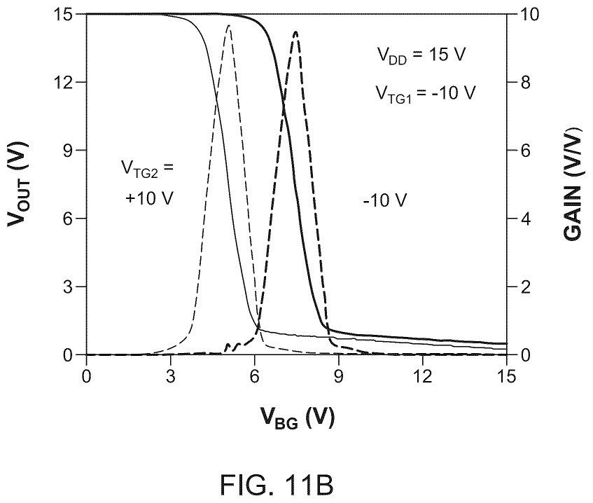

To demonstrate how the dual-gate architecture can be used to fine-tune the operating characteristics of the unipolar inverters, the inventors integrated two In₂O₃ TFTs, one acting as the load and the other as the driver, as schematically illustrated in FIG. 11A. The top-gate control terminal representations of the driver and load device are V_{TG1} and V_{TG2}, respectively. The driver transistor is located in the S1 layer, whilst the load is located in the S2 layer. The output curves and gain characteristics of each inverter measured at fixed V_{TG1} and V_{TG2} voltages (10, 5, 0, −5) were obtained. VTCs measured at V_{DD}=15 V with V_{TG1}=10 V and V_{TG1}=5 V show unbalanced characteristics with a V_{Trip}~−7 and −3 V, respectively, and a maximum signal gain of around 10 V/V. Further reducing V_{TG1} to 0 V and −5 V is shifting the VTCs towards more positive voltages with a V_{Trip} of ~2.5 and ~3 V, respectively, while maintaining the signal gain of about 10. Finally, setting V_{TG1}=−10 V shifts the VTCs further towards positive potentials showing excellent rail-to-rail output voltage (V_{OUT}) swing. The V_{Trip} Of this optimized circuit can be precisely tuned from 5.0 to 7.3 V by changing the V_{TG2} bias from −10 to 10 V, as illustrated in FIG. 11B with no major change in the signal gain characteristics. Notably, when both V_{TG1} and V_{TG2} are set to −10 V, V_{Trip} of the inverter circuit (~7.3 V) is close to V_{DD}/2 showing the optimized circuit configuration. Depending on the selection of V_{TG1} and V_{TG2}, the V_{Trip} can be adjusted over a wide range. Besides V_{Trip}, for different V_{TG2} bias conditions, the noise margin of the optimized inverter circuit is >70%. These results show the special capability of the double-gate architecture to precisely adjust the operating characteristics of the transistors and the ensuing logic circuits. Combined with the 3D-integrated 10-S IC arrangement and the aptitude of the components to be reconfigured, this could be a beneficial technology and create new avenues of research.

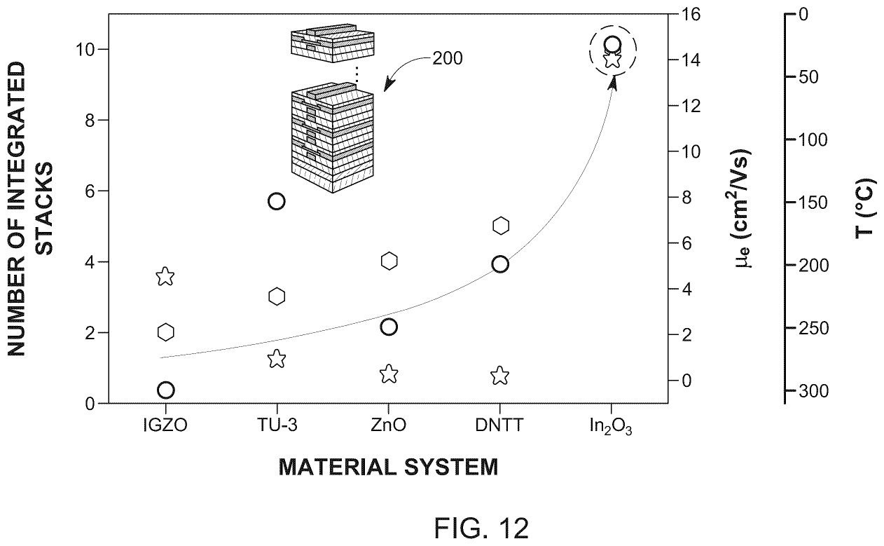

The new approach discussed above for achieving monolithic three-dimensional TFT integration at room temperature or low temperature, with a record number of 10 vertical stacking layers performs better than the existing technologies. FIG. 12 compares the IC 200 discussed above with three-dimensionally integrated TFT technologies from the literature. IC 200 combines impressive performance characteristics, such as a low subthreshold swing (0.4 V/dec), high channel current on/off ratio (10⁸), and high field-effect electron mobility (15 cm²/V·s) across the stack. The dual-gate transistors at different levels in the 10-S were used to create configurable logic inverters that show tunable operating characteristics with signal gain up to 50 V/V. The results presented above for the IC 200 demonstrate the scalability and excellent performance of the 3D-monolithic vertical integration approach, providing another solution for cheaper and highly scalable large-area electronics.

The term “about” is used in this application to mean a variation of up to 20% of the parameter characterized by this term.

It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

The disclosed embodiments provide a method of monolithically integrating dual-gate In₂O₃ TFTs located at different locations in a stack. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] Smith, J. et al. Air-stable solution-processed hybrid transistors with hole and electron mobilities exceeding 2 cm2v-1 s-1. Advanced Materials 22, 3598-3602 (2010).
[2] Jeon, Y. & Kim, S. Vertical stacking of ZnO nanowire devices with different functionalities on plastic substrates, in Physica Status Solidi (A) Applications and Materials Science vol. 211 1928-1932 (Wiley-VCH Verlag, 2014).
[3] Joo et al. Oxide Thin-Film Transistor-Based Vertically Stacked Complementary Inverter for Logic and Photo-Sensor Operations. Materials 12, 3815 (2019).

1. A method for making a vertically integrated circuit, the method comprising:
providing an amorphous oxide semiconductor substrate;
forming a first thin-film transistor over the amorphous oxide semiconductor substrate by using one or more deposition techniques at temperatures equal to or lower than 110° C.;
depositing a buffer layer over the first thin-film transistor, wherein the buffer layer has a melting temperature higher than 110° C.; and
forming a second thin-film transistor directly over the buffer layer by using the one or more deposition techniques at temperatures equal to or lower than 110° C., to form the vertically integrated circuit,
wherein each of the first and second thin-film transistors has a metal oxide channel.

2. The method of claim 1, wherein each of the first and second thin-film transistors is a dual gate transistor.

3. The method of claim 1, wherein the first thin-film transistor is different from the second thin-film transistor.

4. The method of claim 1, wherein the buffer layer includes parylene-C.

5. The method of claim 1, wherein a thickness of the buffer layer is between 40 and 60 nm.

6. The method of claim 1, wherein the one or more deposition techniques includes a chemical vapor deposition method.

7. The method of claim 1, further comprising:
patterning a bottom gate on the amorphous oxide semiconductor substrate;
forming a first dielectric layer on the bottom gate;
forming a channel layer on the first dielectric layer;
forming source and drain regions on the first dielectric layer;
forming a second dielectric layer over the channel layer and the source and drain regions; and
forming a top gate over the second dielectric layer.

8. The method of claim 7, wherein the first dielectric layer, the second dielectric layer, and the buffer layer are made of parylene-C and the channel layer is made of an indium oxide.

9. The method of claim 7, further comprising:
forming additional thin-film transistors, vertically integrated with the first and second thin-film transistors using the one or more deposition techniques at temperatures equal to or lower than 110° C.

10. The method of claim 7, wherein a roughness of any layer of the first and second thin-film transistors is between 1.4 and 4 nm.

11. A vertically integrated circuit comprising:
an amorphous oxide semiconductor substrate;
a first thin-film transistor located over the amorphous oxide semiconductor substrate;
a buffer layer located over the first thin-film transistor, wherein the buffer layer has a melting temperature higher than 110° C. and smaller than 290° C.; and
a second thin-film transistor directly located over the buffer layer,
wherein a thickness of the buffer layer is between 40 and 60 nm, and
wherein each of the first and second thin-film transistors has a metal oxide channel.

12. The circuit of claim 11, wherein each of the first and second thin-film transistors is a dual gate transistor.

13. The circuit of claim 11, wherein the first thin-film transistor is different from the second thin-film transistor.

14. The circuit of claim 11, wherein the buffer layer includes parylene-C.

15. The circuit of claim 11, further comprising:
a bottom gate located on the amorphous oxide semiconductor substrate;
a first dielectric layer located on the bottom gate;
a channel layer located on the first dielectric layer;
source and drain regions located on the first dielectric layer;
a second dielectric layer located over the channel layer and the source and drain regions; and
a top gate located over the second dielectric layer.

16. The circuit of claim 15, wherein the first dielectric layer, the second dielectric layer, and the buffer layer are made of parylene-C.

17. The circuit of claim 15, wherein the channel layer is made of an indium oxide.

18. The circuit of claim 15, wherein a roughness of any layer of the first and second thin-film transistors is between 1.4 and 4 nm.

19. The circuit of claim 15, wherein a thickness of each of the source and drain gates is between 10 and 30 nm.

20. The circuit of claim 11, wherein the first thin-transistor is configured to act as a driver and the second thin-transistor is configured to act as a load to achieve an inverter.
